(19) United States
(12) Patent Application Publication
(10) Pub. No.: US 2008/0169478 A1
(43) Pub. Date: Jul. 17, 2008

(54) Photocoupler

(75) Inventor: Masahiro Muranaka, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 12/008,337

(22) Filed: Jan. 10, 2008

(30) Foreign Application Priority Data
Jan. 12, 2007 (JP) 2007-004365

(51) Int. Cl. H01L 33/00

(52) U.S. Cl. 257/82; 257/E33.077

(57) ABSTRACT

A photocoupler includes a silicon substrate, a light receiving element embedded in the substrate, a transparent insulating film formed on the substrate to cover the light receiving element, and a light emitting element facing the light receiving element via the transparent insulating film. The light emitting element is an organic electroluminescent light source made up of a metal electrode, a transparent electrode, and a light emitting layer disposed between the metal electrode and the transparent electrode.

### BACKGROUND OF THE INVENTION

1. Field of the Invention

The present invention relates to a photocoupler used for e.g. a switching-mode power supply, a signal insulator of a sensor, or an input/output means of electronic equipment such as a communications device.

2. Description of the Related Art

FIG. 3 illustrates a conventional photocoupler disclosed in JP-A-2006-332184. The illustrated photocoupler X includes lead frames 91A, 91B, 91C, an LED element 92, a light receiving element 93, an IC chip 94, a transparent insulating resin 95, and a resin package 96. The LED element 92 is mounted on the lead frame 91A to serve as a light emitting means on the signal input side. The light receiving element 93 is mounted on the lead frame 91B to serve as a light receiving means on the signal output side. The IC chip 94 is mounted on the lead frame 91C to generate output signals according to electro motive force generated by the light receiving element 93. The transparent insulating resin 95, provided between the LED element 92 and the light receiving element 93, is made of an insulating resin that allows the passage of light emitted from the LED element 92. The resin package 96 is made of a nontransparent resin for protecting the LED element 92 and the light receiving element 93, and for shielding light from the outside of the photocoupler X. The photocoupler X can transfer a signal between circuits of different voltages. Without mechanically movable parts, the photocoupler X has a longer life span than a mechanical relay.

However, in manufacture of the photocoupler X, the LED element 92 and the light receiving element 93 need to be prepared separately. Further, it is required to position the lead frame 91A relative to the lead frame 91B accurately, so that light from the LED element 92 is properly received by the light receiving element 93. Still further, after forming the transparent insulating resin 95 between the LED element 92 and the light receiving element 93, the resin package 96 needs to be formed additionally. Due to these steps required for manufacturing the photocoupler X, it is difficult to improve the productive efficiency. In the photocoupler X, the LED element 92 and the light receiving element 93 are arranged to face each other and sealed by the resin package 96. This configuration, however, makes the thickness of the device unduly large.

### SUMMARY OF THE INVENTION

The present invention has been proposed under the above-described circumstances. It is therefore an object of the present invention to provide a compact photocoupler whose structure is suitable for enabling efficient production.

According to the present invention, there is provided a photocoupler comprising: a substrate; a light receiving element formed at the substrate; a transparent insulating film covering the light receiving element; and a light emitting element facing the light receiving element via the transparent insulating film, wherein the light emitting element is an electroluminescent element.

Preferably, the substrate may be made of silicon.

Preferably, the transparent insulating film may be smaller in thickness than the substrate.

Preferably, the light receiving element may be embedded in the substrate.

Preferably, the light emitting element may comprise a metal electrode, a transparent electrode, and a light emitting layer between the metal electrode and the transparent electrode.

### BRIEF DESCRIPTION OF THE DRAWINGS

FIG. 1 is a plan view illustrating the principal portions of a photocoupler according to the present invention.

FIG. 2 is a sectional view taken along lines II-II in FIG. 1.

FIG. 3 is a sectional view illustrating a conventional photocoupler.

### DETAILED DESCRIPTION OF THE PREFERRED EMBODIMENTS

Preferred embodiments of the present invention will be described below with reference to the accompanying drawings.

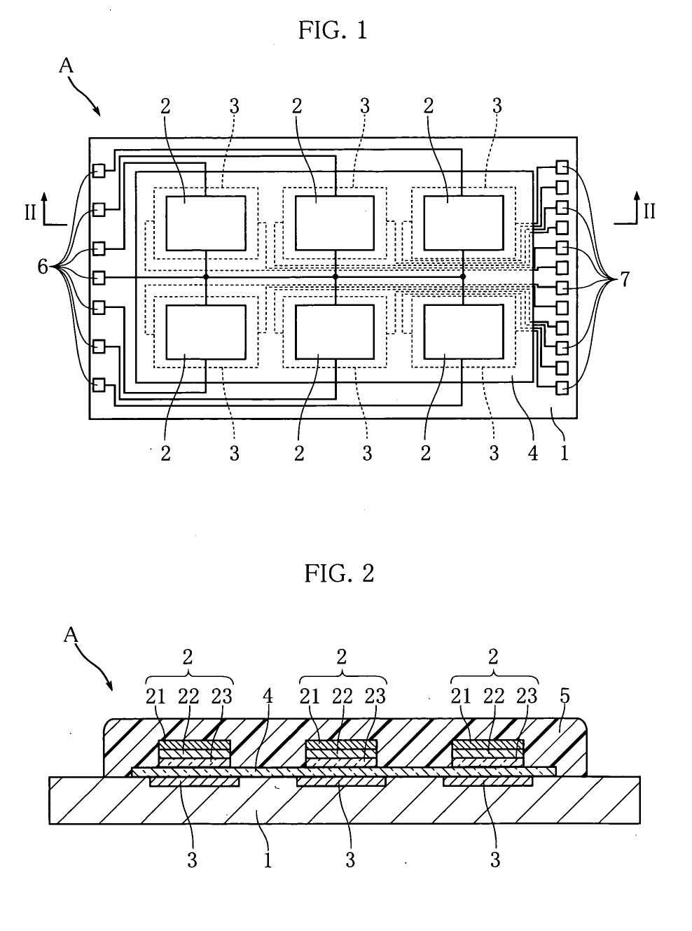

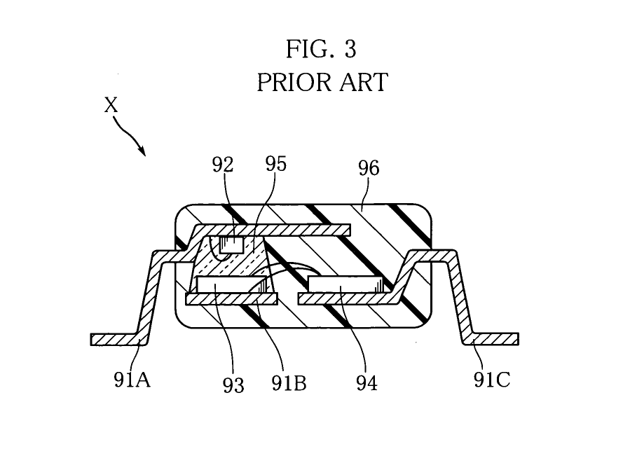

FIGS. 1 and 2 show an example of a photocoupler according to the present invention. The illustrated photocoupler A includes a substrate 1, six light receiving elements 3, six organic EL (electroluminescence) elements 2, a transparent insulating film 4, a resin package 5 (not shown in FIG. 5), a plurality of input terminals 6, and a plurality of output terminals 7. The photocoupler A transfers a signal supplied from an input circuit to an output circuit, while keeping these two circuits electrically insulated from each other.

The substrate 1 is a rectangular plate which may be elongated in one direction, as seen from FIG. 1. The substrate 1 is made of silicon (Si).

The light emitting elements 3 generate electromotive force upon receipt of light. In the present embodiment, the light receiving elements 3 are disposed in a matrix arrangement on the substrate 1. As seen from FIG. 2, each of the light emitting elements 3 is formed integral in the substrate 1

The transparent insulating film 4 is made of glass, SiO₂, or SiN, for example, and allows the passage of light from the organic EL elements 2. The transparent insulating film 4 covers the light receiving elements 3 and has a thickness of about several tens of micrometers. The insulating film 4 may be smaller in thickness than the substrate 1 or even the light receiving elements 3. The insulating film 4 covers only the upper surface, but not the side surface nor bottom surface of each light receiving element 3. The transparent insulating film 4 may be formed by printing e.g. a glass-containing paste on the substrate 1 and then baking the applied paste.

The organic EL elements 2 emit light upon receiving an input signal. In the present embodiment, the organic EL elements 2 are disposed in a matrix arrangement, each facing a corresponding one of the light receiving elements 3 via the transparent insulating film 4.

As shown in FIG. 2, each organic EL element 2 has a laminate structure comprising a metal electrode 21, an organic light emitting layer 22, and a transparent electrode 23 that is directly formed on the insulating film 4. The transparent electrode 23 is a conductive element made of ITO (Indium Tin Oxide), for example, and serves as a common electrode. The organic light emitting layer 22 has a laminate structure comprising a plurality of layers made of organic materials, such as a hole-injection layer, a hole-transport layer, a light emitting layer, an electron-transport layer, and an electron-injection layer. The metal electrode 21 is made of Al, for example, and serves as an individual electrode. When electrons from the transparent electrode 23 and holes from the metal electrode 21 recombine in the organic light emitting layer 22, light is emitted, where the wavelength of the light depends on the organic material of the light emitting layer 22. The organic EL elements 2 may be formed by printing laminate layers for the metal electrode 21, the organic light emitting layer 22 and the transparent electrode 23, and then patterning the laminate layers into the prescribed form.

The resin package 5, made of a nontransparent insulating resin for example, directly covers the organic EL elements 2 and the transparent insulating film 4 (thereby indirectly covering the light receiving elements 3). The resin package 5 is formed by the molding of a nontransparent insulating resin material. In the illustrated example, the resin package 5 is not provided over the entire area of the upper surface of the substrate 1, but only partially provided so that the input terminals 6 and the output terminals 7 are exposed for external connection. With such an arrangement, as viewed in plan (i.e., as viewed from the above in FIG. 2), the resin package 5 is smaller in area than the substrate 1.

As shown in FIG. 1, the input terminals 6, made of e.g. Au, are arranged in a row extending along one end (the left end in the illustrated example) of the substrate 1. The input terminals 6, seven in total, are connected to the metal electrode 21 and the transparent electrode 23 of the organic EL elements 2 via wires. More specifically, the middle terminal 6 is connected to all the transparent electrodes 23 of the respective EL elements 2, while the other six terminals 6 (the upper and lower terminals relative to the middle terminal) are connected to a corresponding one of the metal electrodes 21 of the respective EL elements 2. When an input signal is inputted to one of the upper or lower terminals 6, the organic EL element 2 corresponding to the selected terminal 6 emits light.

The output terminals 7, made of e.g. Au, are arranged in a row extending along the other end (the right end) of the substrate 1. The output terminals 7, twelve in total, are connected to the light receiving elements 3 via wires. More specifically, the output terminals 7 are grouped into six pairs, and the output terminals 7 in each pair are connected to a corresponding one of the light receiving elements 3. In this configuration, when light emitted from a selected EL element 2 is received by the corresponding light receiving element 3, an output signal is generated by this element 3 to be sent out via the relevant output terminals 7.

Next, the advantages of the photocoupler A will be described below.

According to the present invention, as described above, six light receiving elements 3 are formed in the substrate 1, and then a transparent insulating film 4 is formed to cover these light receiving elements. Thereafter, six organic EL elements 2 are formed on the transparent insulating film 4 by a printing technique so that the organic EL elements 2 face the light receiving elements 3, one-to-one. In this way, in contrast to the prior art, there is no need to separately prepare a light receiving element and an organic EL element and perform the painstaking positioning of them. Accordingly, the photocoupler A of the present invention is manufactured efficiently.

Since the photocoupler A has a closely laminate structure (made up of the substrate 1, the light receiving elements 3, the transparent insulating film 4, and the organic EL elements 2), its thickness is advantageously reduced. Further, the thickness of the transparent insulating film 4 can be very small, for example, several tens of micrometers. Thus, light from the organic EL elements 2 is much less likely to be directed to a non-corresponding light receiving element 3 in error. Therefore, it is possible to transfer two or more signals simultaneously between the organic EL elements 2 and the light receiving elements 3.

By using a substrate made of Si, the light receiving elements 3 can be formed in the substrate, so embedded as not to bulge above the surface of the substrate. This is advantageous to keeping the surface of the substrate 1 flat, thereby facilitating the forming of the organic EL elements 2 by e.g. printing on the substrate 1. It is also possible to reduce the overall thickness of the photocoupler A.

The photocoupler according to the present invention is not limited to the above-described embodiment. For example, the EL elements in the present invention may be inorganic elements in place of the organic elements. The photocoupler may not necessarily be of the above-described array type that is capable of performing parallel signal connection, but may be of the type capable of transmitting a single signal at one time. According to the present invention, the device may be constituted as a photo IC or photo MOS relay incorporating an integrated circuit for signal processing.

1. A photocoupler comprising:
a substrate;
a light receiving element formed at the substrate;
a transparent insulating film covering the light receiving element; and
a light emitting element facing the light receiving element via the transparent insulating film, the light emitting element being an electroluminescent element.

2. The photocoupler according to claim 1, wherein the substrate is made of silicon.

3. The photocoupler according to claim 1, wherein the transparent insulating film is smaller in thickness than the substrate.

4. The photocoupler according to claim 1, wherein the light receiving element is embedded in the substrate.

5. The photocoupler according to claim 1, wherein the light emitting element comprises a metal electrode, a transparent electrode, and a light emitting layer between the metal electrode and the transparent electrode.
